(19) United States
(12) Patent Application Publication
(10) Pub. No.: US 2015/0263484 A1
(43) Pub. Date: Sep. 17, 2015

(54) HEATING ELEMENT FOR HYBRID SILICON/III-V COMPOUND SEMICONDUCTOR DEVICES

(71) Applicant: Emcore Corporation, Albuquerque, NM (US)

(72) Inventor: Jia-Sheng Huang, South Pasadena, CA (US)

(73) Assignee: Emcore Corporation, Albuquerque, NM (US)

(21) Appl. No.: 14/281,632

(22) Filed: May 19, 2014

Related U.S. Application Data
(63) Continuation-in-part of application No. 14/209,778, filed on Mar. 13, 2014.

(51) Int. Cl. H01S 5/024; H01S 5/30; H01S 5/02

(52) U.S. Cl. CPC H01S 5/02453; H01S 5/021; H01S 5/0215; H01S 5/0203; H01S 5/3013

(57) ABSTRACT

A hybrid silicon/III-V compound semiconductor laser device comprising a silicon substrate including a channel configured for silicide line formation as a function of current through the channel; so that the temperature of the laser device is adjusted to a predetermined level.

### REFERENCE TO RELATED APPLICATIONS

This application is a continuation-in-part of U.S. patent application Ser. No. 14/209,778 filed Mar. 13, 2014, which is herein incorporated by reference in its entirety. Further, this application is related to co-pending U.S. patent application Ser. No. 14/146,772 filed Jan. 2, 2014, which is herein incorporated by reference in its entirety.

### BACKGROUND OF THE INVENTION

1. Field of the Invention

The field of the invention relates to semiconductor devices and more particularly to hybrid silicon/III-V compound semiconductor devices, such as semiconductor laser devices.

2. Description of the Related Art

### SUMMARY OF THE INVENTION

### Objects of the Invention

It is an object of this disclosure to provide an integrated silicon and III-V compound semiconductor device to enable adjustable temperature control of the III-V compound semiconductor device by electrically adjusting a silicide channel in the silicon device.

It is another object of the disclosure to provide an adjustable electrically resistive element for use in a hybrid photonics device.

It is another object of the disclosure to provide a continuously electronically controllable resistive element in an electro-optical semiconductor device.

It is another object of the disclosure to provide a continuously tunable heater in an electro-optical semiconductor device wherein the heater can be adjusted by controlling the electrical current

It is still another objective of the disclosure to provide an electronic element for adjusting SBS suppression in a laser semiconductor device.

It is still another object of the disclosure to provide a silicide line on a silicon semiconductor device to enable a continuously electrically controllable adjustment of an adjoining laser by varying the current through the line.

It is an object of this disclosure to provide an integrated silicon and III-V compound semiconductor device to enable adjustable temperature control of the III-V compound semiconductor device by electricity adjusting the silicon device.

It is another object of the disclosure to provide an adjustable electrically resistive element for use in a hybrid photonics device.

It is another object of the disclosure to provide a continuously electronically controllable resistive element in an electro-optical semiconductor device.

It is another object of the disclosure to provide a continuously tunable heater in an electro-optical semiconductor device wherein the heater can be adjusted by controlling the electrical current

It is still another objective of the disclosure to provide an electrically adjustable electronic element for setting the level of SBS suppression in a laser semiconductor device.

It is still another object of the disclosure to provide a silicide line on a silicon semiconductor device to enable a continuously electrically controllable adjustment of an adjoining laser semiconductor device by varying the current through the line.

Some implementations of the present disclosure may incorporate of implement fewer of the aspects and features noted in the foregoing objects.

### Features of the Disclosure

Briefly, and in general terms, the present disclosure provides a method of adjusting an operational parameter in a III-V compound semiconductor device comprising: providing a silicon substrate including a channel configured for silicide line formation as a function of current through the channel; coupling the silicon substrate to the III-V compound semiconductor device so that the temperature of the silicon substrate is radiated to the III-V compound semiconductor device: and controlling the current through the channel so that the temperature of the semiconductor device is adjusted to a predetermined level, thereby controllably adjusting the operational parameter of the semiconductor device.

In another aspect, the present disclosure provides a method of controlling the temperature of a hybrid silicon/III-V compound semiconductor device for controllably adjusting an operational parameter of such device.

In another aspect, the present disclosure provides a hybrid silicon/III-V compound semiconductor device comprising: a silicon substrate including a channel configured for silicide line formation as a function of current through the channel; and a semiconductor laser device implemented on the III-V compound semiconductor portion of the hybrid device mounted on the silicon substrate.

In another aspect, the present disclosure provides a hybrid silicon/III-V compound semiconductor device including a silicon substrate including a channel configured for silicide line formation as a function of current through the channel; and a electro-optical device implemented on the III-V compound semiconductor portion of the hybrid device mounted on the silicon substrate.

In another aspect, the present disclosure provides a heating element coupled to a hybrid silicon/III-V compound semiconductor device including a silicon substrate including a channel configured for silicide line formation as a function of current through the channel that forms the heating element; and a electro-optical device implemented on the III-V compound semiconductor portion of the hybrid device mounted on the silicon substrate whose temperature is controlled by the heating element.

In some embodiments, the hybrid silicon/III-V compound semiconductor device is a laser with an integrated heater.

In some embodiments, the hybrid silicon/III-V compound semiconductor device is a gain chip with an integrated heater for use in an external cavity laser.

In some embodiments, the silicon substrate is n conductivity type and the first portion of the silicon substrate is a p-conductivity type region disposed in the semiconductor substrate, the p-conductivity type region having a first end and a second end forming a channel there between.

In some embodiments, a first electrical terminal composed of nickel or copper is disposed on the first end of the p-conductivity type region.

In some embodiments, a second electrical terminal composed of nickel or copper is disposed on the second end of the p-conductivity type region.

In some embodiments, an electromigration-induced silicide line is formed in the channel between the first and the second electrical terminals when a current is applied to the terminals.

In some embodiments, the channel is between 150 and 200 micrometers long and between 1 and 10 micrometers wide.

In some embodiments, the channel is between 150 and 200 micrometers long and between 0.5 and 1.5 micrometers wide.

In some embodiments, the applied current is between 60 and 90 mA.

In some embodiments, the applied current is between 70 and 80 mA.

In some embodiments, the applied current is about 80 mA.

In some embodiments the silicide line is between 1 and 2 microns in width, and less than one micron in depth.

In some embodiments the silicide line is between 0.5 and 1 micron in width, and less than one-half micron in depth.

In some embodiments the silicide line is about 0.5 micron in width, and about 0.5 micron in depth.

In some embodiments, the channel is between 150 and 200 micrometers long and between 0.5 and 1.5 micrometers wide, and the applied current is about 80 mA.

In some embodiments, the III-V compound semiconductor device is a laser having a front facet and a rear facet, and wherein the channel extends longitudinally between the region adjacent to the front facet to the region adjacent to the rear facet.

In some embodiments, current is applied so that a low resistance region is formed in the channel adjacent to the front facet, and a high resistance region is formed in the channel adjacent to the rear facet.

In some embodiments, current is applied so that a low resistance region is formed in the channel adjacent to the rear facet, and a high resistance region is formed in the channel adjacent to the front facet.

In some embodiments, the length of the silicide line is determined to provide a predetermined resistance level, and thereby a predetermined level of SBS suppression and current is applied to the terminals to the extent required to implement the predetermined resistance level.

In some embodiments, the silicide line extends from the terminal which is the cathode terminal to a point between the cathode terminal and the anode terminal so as to provide a predetermined resistance level.

In some embodiments, the III-V compound semiconductor device is a laser having a front facet and a rear facet, and wherein the channel extends longitudinally between the region adjacent to the front facet to the region adjacent to the rear facet.

In some embodiments, current is applied so that a low resistance region is formed in the channel adjacent to the front facet, and a high resistance region is formed in the channel adjacent to the rear facet.

In some embodiments, current is applied so that a low resistance region is formed in the channel adjacent to the rear facet, and a high resistance region is formed in the channel adjacent to the front facet.

In some embodiments, the silicide line extends a predetermined length from the terminal adjacent to the front facet of the laser, to a point in the channel between the front facet and the rear facet of the laser.

Some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teachings herein will recognize additional applications, modifications and embodiments in other fields, which are within the scope of the disclosure as disclosed and claimed herein and with respect to which the disclosure could be of utility.

### BRIEF DESCRIPTION OF THE DRAWINGS

The invention will be better and more fully appreciated by reference to the following detailed description when considered in conjunction with the accompanying drawings, wherein:

FIG. 1 is a schematic diagram of a silicide line structure in a semiconductor substrate in accordance with an illustrated embodiment of the disclosure;

FIG. 2 is a graph of the current-voltage (IN) curve of the illustrated test structure of FIG. 1 at various temperature levels;

FIG. 3 is a plot of the resistance (R) of the silicide line test structure of FIG. 1 as a function of current (I);

FIG. 4A is a graph that shows the length of the silicide line as a function of applied current;

FIG. 4B is a graph that shows the resistance reduction in the channel as a function of the length of the silicide line;

FIG. 5A is a perspective view of a silicon substrate for processing according to the present disclosure;

FIG. 5B is a perspective view of a silicon substrate of FIG. 5A after the first process step:

FIG. 6A is a perspective view of a silicon substrate of FIG. 5B after the next process step;

FIG. 6B is a cross-sectional view of the substrate of FIG. 6A through the 6B-6B plane;

FIG. 6C is a cross-sectional view of the substrate of FIG. 6A through the 6B-6B plane after the next process step;

FIG. 6D is a cross-sectional view of the substrate of FIG. 6A through the 6B-6B plane after the next process step;

FIG. 6E is a cross-sectional view of the substrate of FIG. 6A through the 6B-6B plane after the next process step;

FIG. 6F is a cross-sectional view of the substrate of FIG. 6A through the 6B-6B plane after the next process step;

FIG. 7A is a perspective view of a Ill-V compound semiconductor substrate prior to execution of a sequence of process steps according to the present disclosure;

FIG. 7B is a perspective view of the substrate of FIG. 7A after the next sequence of process steps;

FIG. 7C is a cross-sectional view of a portion of the substrate of FIG. 7B;

FIG. 8A is a perspective of a hybrid silicon/III-V compound semiconductor structure;

FIG. 8B is a cross-sectional view of a portion of the structure of FIG. 8A;

FIG. 9A is a perspective of a hybrid silicon/III-V compound semiconductor structure showing the waveguide in the silicon portion;

FIG. 9B is a top view of the hybrid silicon/III-V compound semiconductor structure after the III-V compound semiconductor structure is joined to the silicon portion of the structure that was depicted in FIG. 8A;

FIG. 10A is the first example of thermal tuning by electrical current through the channel illustrating the situation when no silicide line is formed in the semiconductor region, and the channel is at high resistance state;

FIG. 10B is an example of thermal tuning by the electrical current illustrating the situation where a short silicide line is formed in the semiconductor region, and the channel is at medium resistance state;

FIG. 10C is an example of thermal tuning by the electrical current illustrating the situation where a long silicide line is formed in the semiconductor region, and the channel is at low resistance state;

FIG. 11A is another embodiment of the present disclosure illustrating the control of the laser gain medium by implementation of a low resistance at the rear laser section; and

FIG. 11B is another embodiment of the present disclosure illustrating the control of the laser gain medium by implementation of a low resistance at the front laser section.

FIG. 12 is a graph that shows the laser wavelength as a function of temperature in a DFB InP laser device according to the present disclosure.

FIG. 13 is a graph that shows the laser wavelength as a function of temperature in a FP InP laser device according to the present disclosure.

### DESCRIPTION OF ILLUSTRATIVE EMBODIMENTS

Details of the present disclosure will now be described, including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of actual embodiments nor the relative dimensions of the depicted elements, and are not drawn to scale.

In one embodiment, the present disclosure provides a tunable Si/silicide heater for use in silicon (Si) photonics and hybrid Si/III-V compound semiconductor photonic integrated circuits. The fundamental principle of implementation of the tunable heater is based on electromigration-induced silicide line formation in a p+-Si channel formed in the silicon substrate. In some embodiments, the choice of the metal contact to the channel includes nickel (Ni) and copper (Cu). For the case of Ni contact, the silicide line consists of epitaxial nickel silicide. The p+-Si tunable heater can be integrated into the silicon chip and adjoined with a III-V compound semiconductor device such as an electro-optical device, e.g. a laser or optical modulator.

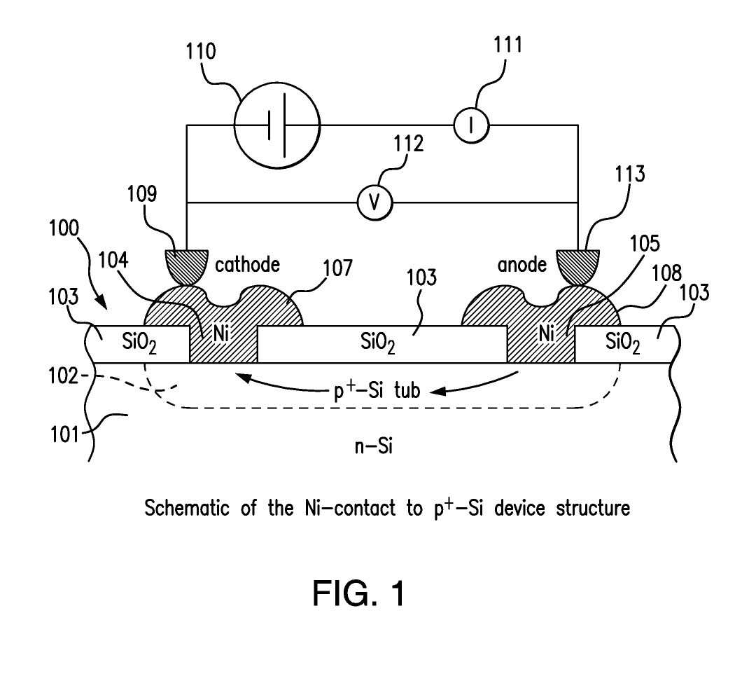

FIG. 1 shows a simplified cross-sectional view of a silicide channel structure based on nickel metal contact to p+ type conductivity silicon semiconductor substrate utilized in embodiments of the present disclosure. In some embodiments, the depicted structure may be fabricated by starting with a (100) n-Si wafer 101 which is deposited with a 300 nm thick silicon dioxide layer. Photolithography and buffered HF acid are then used to define the silicon channel regions 102 in the oxide. A screen oxide of 20 nm may be grown for capping and filtering during the subsequent ion implantation steps.

In some embodiments, the n-Si wafer was implanted with a dose of 5×10¹⁵ ions/cm² of BF2+ accelerated to 40 keV without removing the capping oxide. In some embodiments, post-implantation annealing at 900 degrees Centigrade for 30 minutes in a nitrogen ambient atmosphere is carried out to activate the borant dopant.

Following ion implantation, another 300 nm low temperature oxide layer 103 was grown on the silicon substrate 102. A pair of contact windows 104, 105 were opened through the oxide layer 103 by photolithography and buffered HF etch. Finally, a 260 nm thick metal film which may be composed of (Ni, Co, Ti, Al or Cu) was deposited to make ohmic contacts to the p+-Si. The metal bondpads 107, 108 were defined by photolithography and finished by the lift-off process.

For the specific embodiment of the present disclosure, for a hybrid silicon/III-V compound semiconductor device, nickel (Ni) or copper (Cu) metal contact materials were chosen to facilitate effective silicide line formation and resistance reduction.

To illustrate the testing and characterization of the silicide channel structure, a power source 110 may be coupled to the terminals 104 and 105 by means of leads or contacts 109 and 113 respectively. A voltage meter 112 may be coupled between the leads 109 and 113, and a current meter 111 may be coupled in series with the power source 110 and the lead 113.

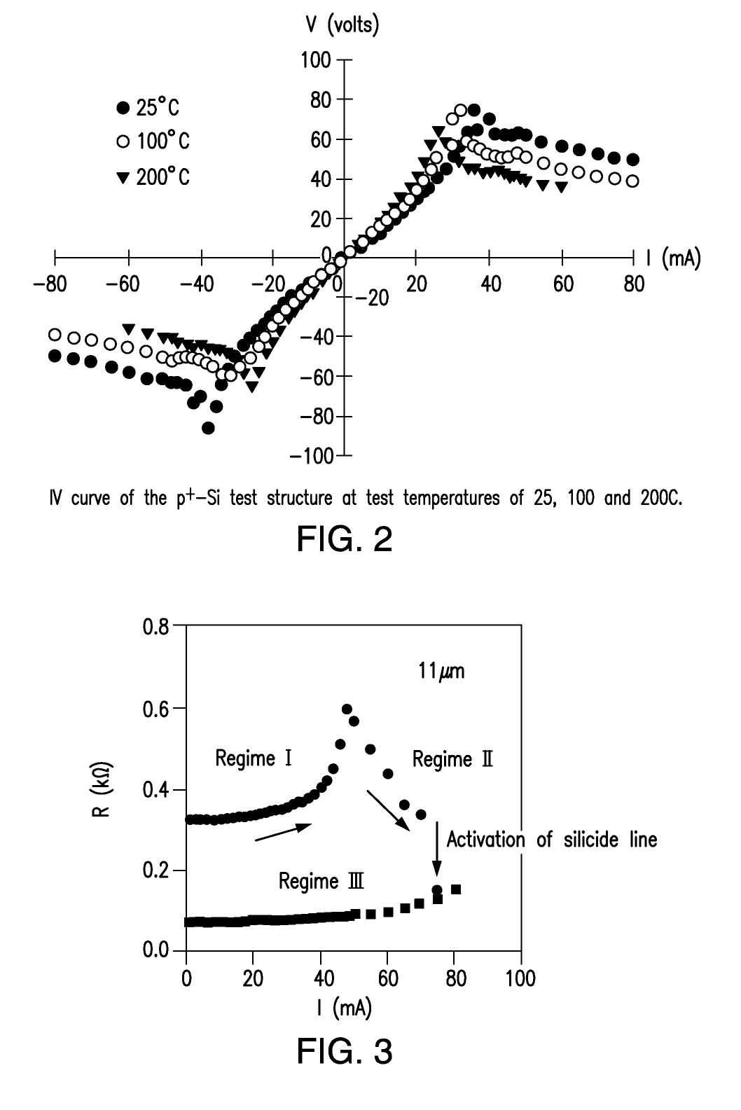

FIG. 2 is a graph of the current-voltage (I-V) curve of the illustrated test structure of FIG. 1 measured at various temperature levels, specifically 25 degrees C., 100 degrees C., and 200 degrees C.

FIG. 3 shows a graphic representation resistance (R) vs. current (I) curve of the p+-Si channel in a specific embodiment of a channel that is configured in an embodiment that is 175 micrometer long and 11 micrometer wide. The resistance curve exhibits three different regimes. In the region which is labeled “Regime I”, the resistance increased gradually in a non-ohmic manner and reaches a maximum value defined as the “critical current”. In the region labeled “Regime II”, the resistance decreases gradually to below the original value. At the critical value of the “activation current”, the resistance decreases precipitously due to silicide line formation and follows the curve depicted in Regime III.

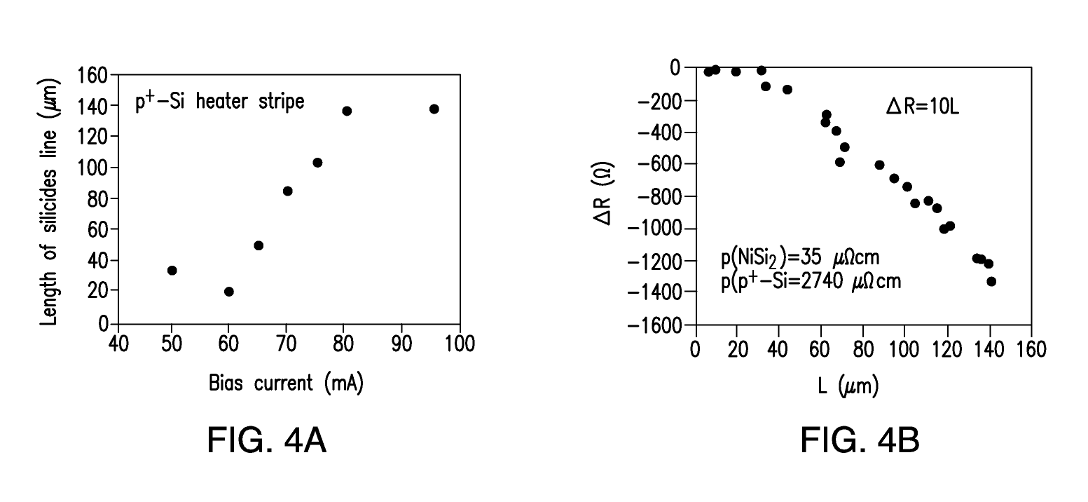

FIG. 4A shows a graph depicting the length of silicide line as a function of applied current for one embodiment or example. The silicide line increased linearly with increasing current between 60 and 80 mA. Above 80 mA, the silicide line reaches the maximum length where the line nearly connects the anode and the cathode contacts.

FIG. 4B shows the resistance reduction in the material as a result of silicide line formation. In the depicted embodiment, the resistance of the channel decreases by about 10 ohms for each micrometer formation of NiSi₂ line.

The use of a p+-Si channel heater stripe with silicide line formation has a variety of broad applications in semiconductor devices in which one or more operational parameters of the semiconductor device is desired to be electrically controlled by adjusting the resistance of an element in the device, including electro-optical devices such as lasers, modulators and other photonic devices. Such control may be performed at the time of manufacturing, thereby adjusting the specific parameters of manufactured batches, in the field during deployment and installation, or subsequently when the device is in operation and use by an end-user.

In the present disclosure, we first present the fabrication of an integrated silicon and III-V compound semiconductor device utilizing a silicide line in the silicon device to enable adjustable temperature control of the III-V compound semiconductor device, and in particular illustrate the embodiment of a laser in which the level of SBS suppression is controlled or set by means of electrically adjusting the level of current through the silicide line, and/or selecting the polarity of the terminals for applying the current to the silicide line with respect to the front/rear facets of the laser.

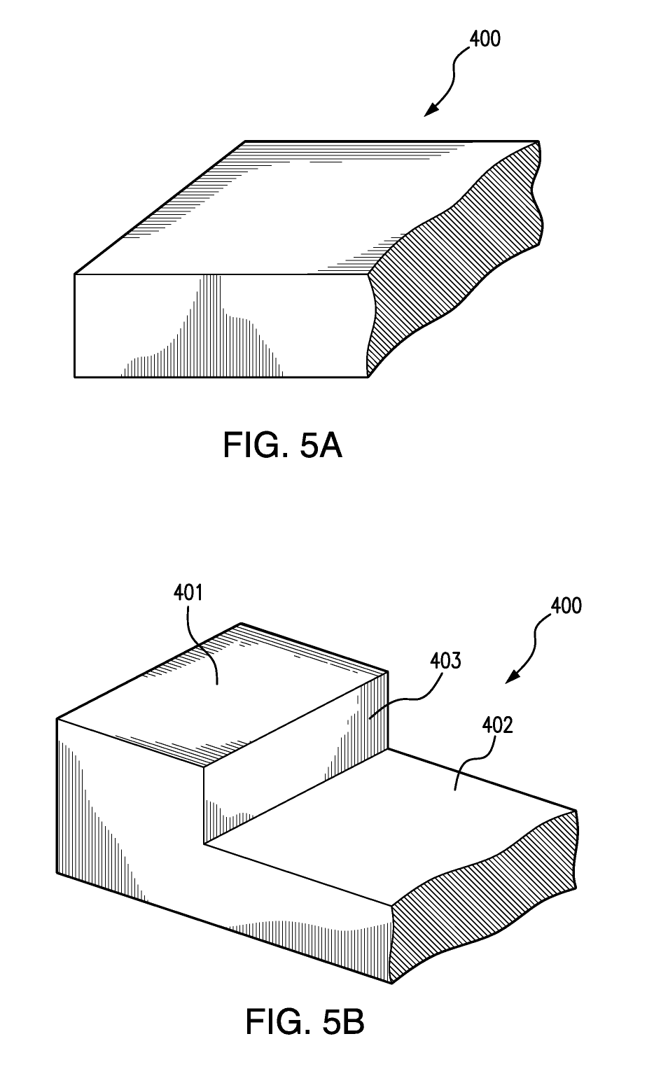

FIG. 5A is a perspective view of a silicon substrate 400 of n type conductivity for processing for fabrication of an integrated silicon and III-V compound semiconductor device according to one embodiment of the present disclosure.

FIG. 5B is a perspective view of a silicon substrate 400 of FIG. 5A after the first process step. In this step a portion of the silicon substrate 400 is removed along a plane 403 extending vertically from the top surface of the substrate in order to form a planar ledge 402 to accommodate the mounting and placement of the III-V compound semiconductor device according to one embodiment of the present disclosure.

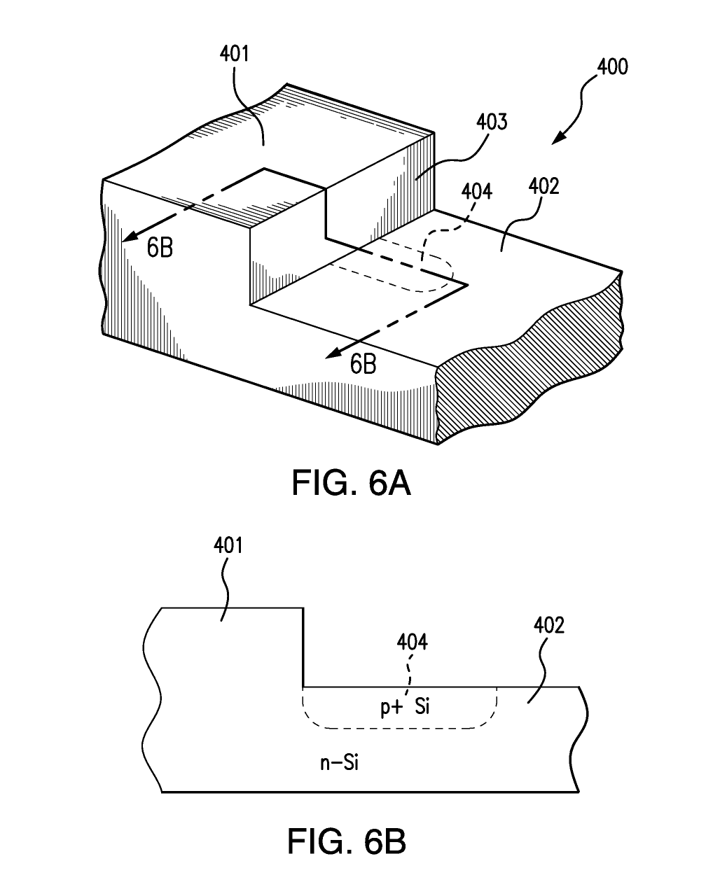

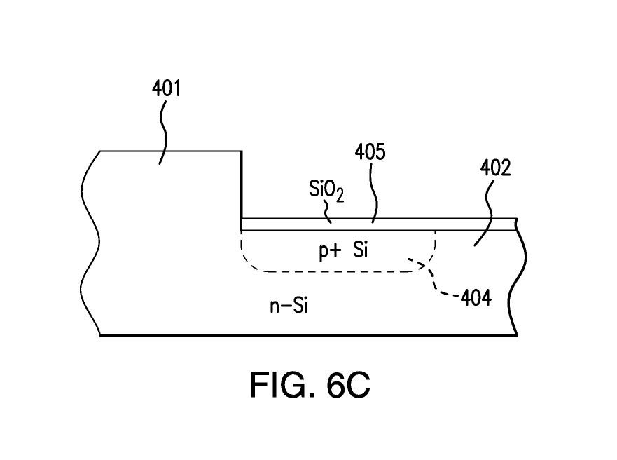

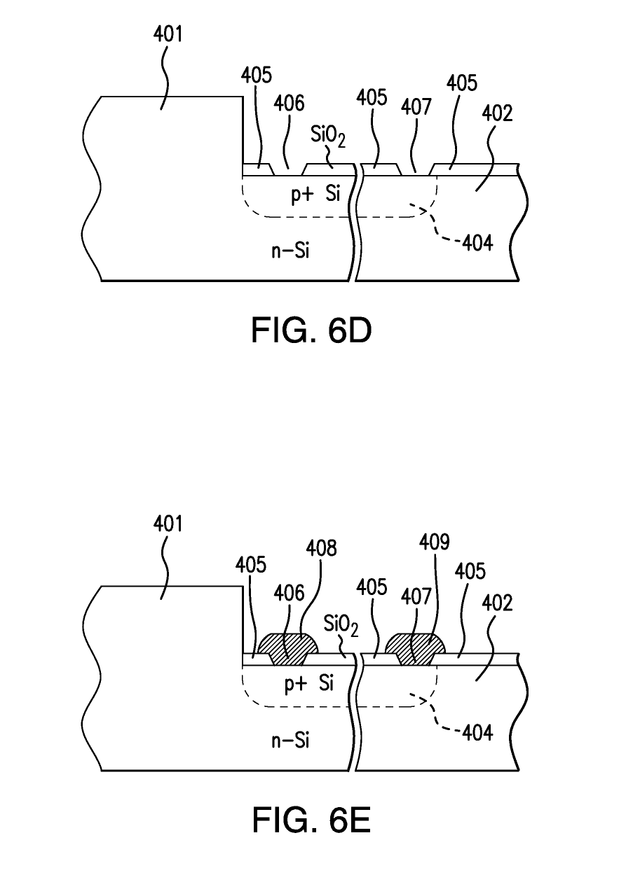

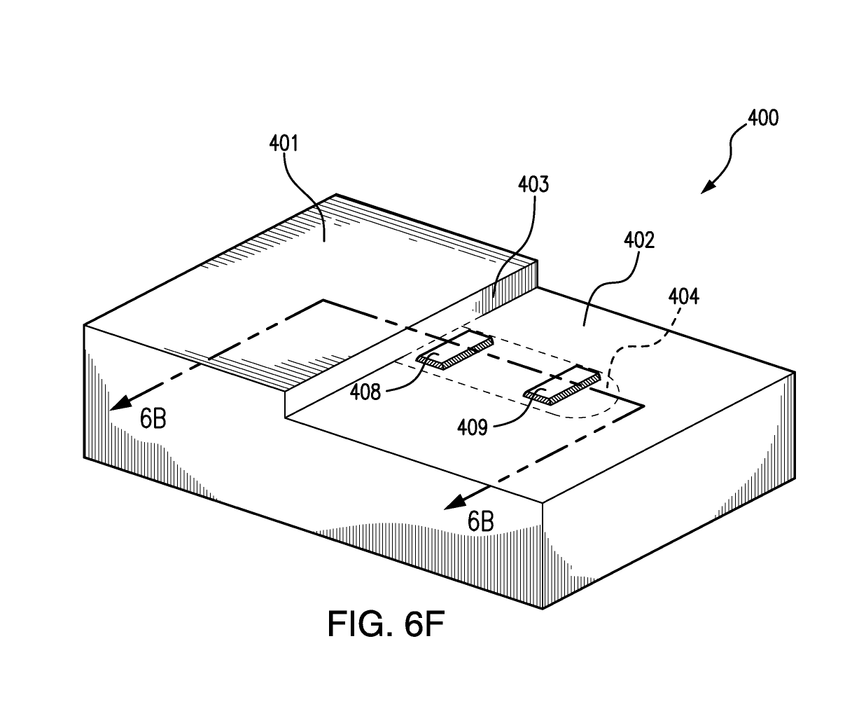

FIG. 6A is a perspective view of a silicon substrate of FIG. 5B after the next process step in which a generally rectangular shaped region 404 of the ledge 404 is doped to become p+ conductivity type according to one embodiment of the present disclosure.

FIG. 6B is a cross-sectional view of the substrate of FIG. 6A through the 6B-6B plane, showing the depth of the region 404 into the ledge 402.

FIG. 6C is a cross-sectional view of the substrate of FIG. 6B through the 6B-6B plane after the next process step in which a silicon dioxide layer 405 is formed over the top surface of the ledge 402.

FIG. 6D is a cross-sectional view of the substrate of FIG. 6C through the 6B-6B plane after the next process step. Two discrete spaced apart openings 406 and 407 are formed in the silicon dioxide layer 405 to allow contacts to be made to the surface of the region 404.

FIG. 6E is a cross-sectional view of the structure of FIG. 6D through the 6B-6B plane after the next process step. Metal contacts 408 and 409 are deposited in openings 406 and 407 to allow electrical contact to the made to two ends of the region 404.

FIG. 6F is a perspective view of the structure of FIG. 6E.

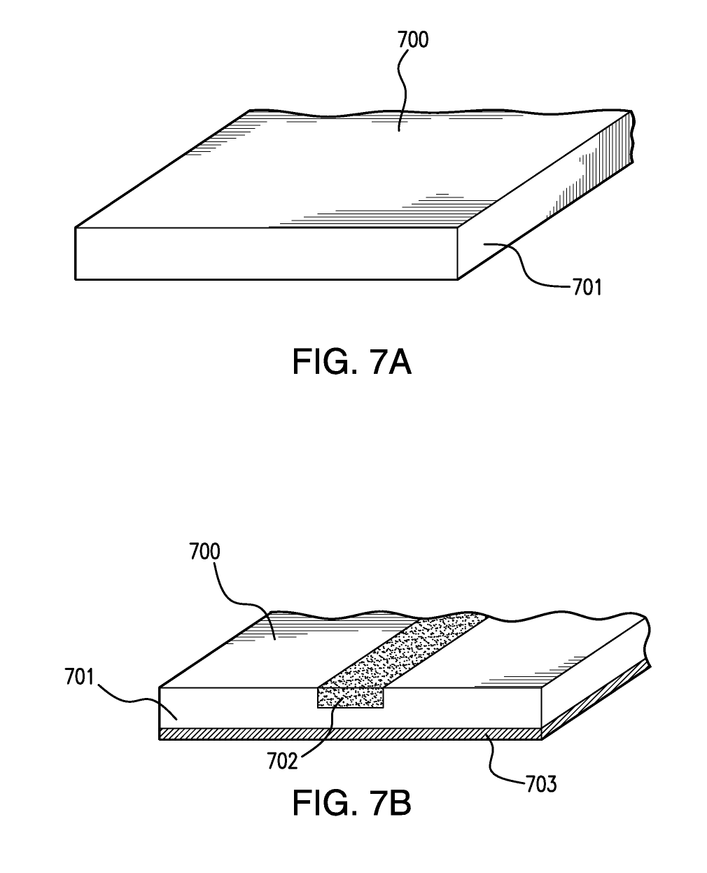

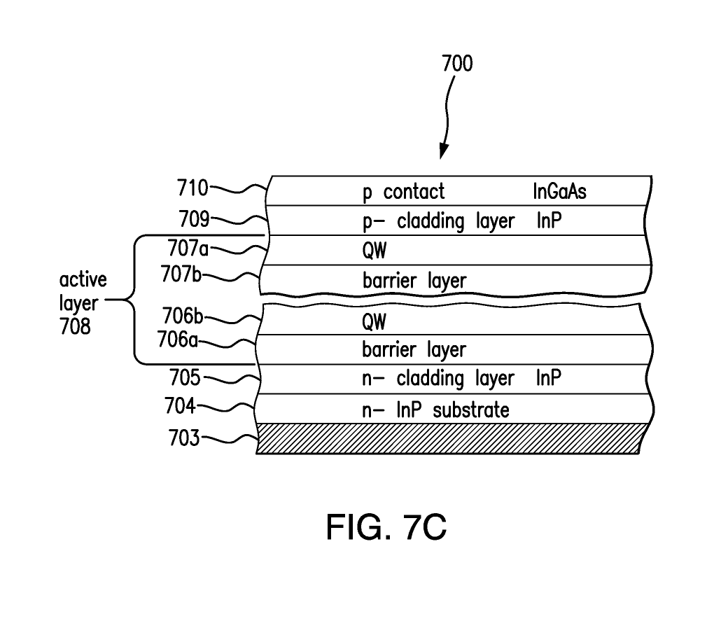

FIG. 7A is a perspective view of a III-V compound semiconductor substrate 701 having a top surface 700, prior to execution of a sequence of process steps according to the present disclosure.

FIG. 7B is a perspective view of the substrate 701 of FIG. 7A after the next sequence of process steps in which a back metal 703 is applied to the backside surface of the substrate 701, and a waveguide or other active layered structures 702 are implemented in an elongated portion of the top surface 700 of the substrate 701.

FIG. 7C is an enlarged cross-sectional view of a portion of the substrate of FIG. 7B depicting one embodiment of the layers constituting a waveguide or other active layered structures 702 disposed in the elongated portion of the top surface 700 of the substrate 701.

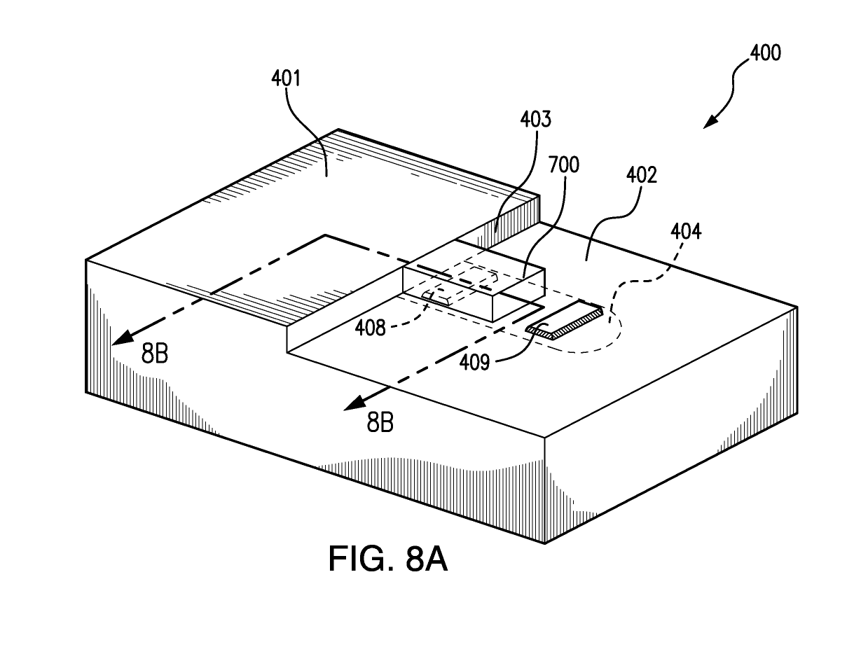

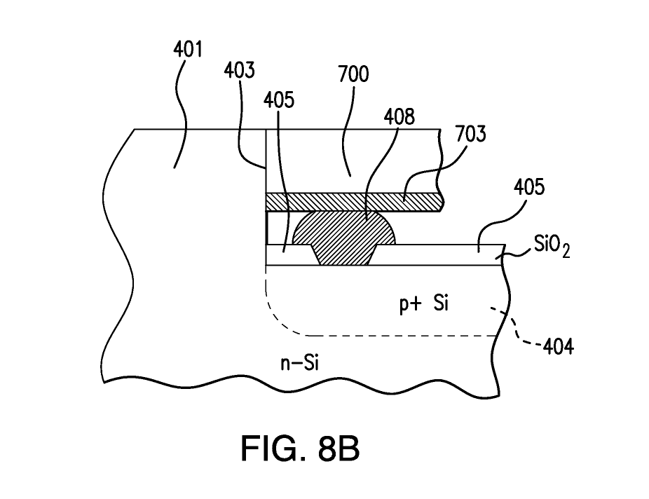

FIG. 8A is a perspective of a hybrid silicon/III-V compound semiconductor structure according to one embodiment of the present disclosure in which the substrate 701 is placed on a portion of the ledge 402 so that it overlies the region 402. In one embodiment, as depicted in FIG. 8A, the planar top surface 700 of the substrate 701 is coplanar with the top surface 401 of the substrate 400, and the side edge of the substrate 701 abuts the edge surface 403 extending vertically from the top surface 401.

FIG. 8B is a cross-sectional view of a portion of the structure of FIG. 8A depicting the electrical contact between the back metal layer 703 of the substrate 701 and the metal contact 408. In other embodiments, the substrate 701 may be spaced apart from the edge 4503, and the back metal layer 703 of the substrate 701 makes electrical contact with the other metal contact 409.

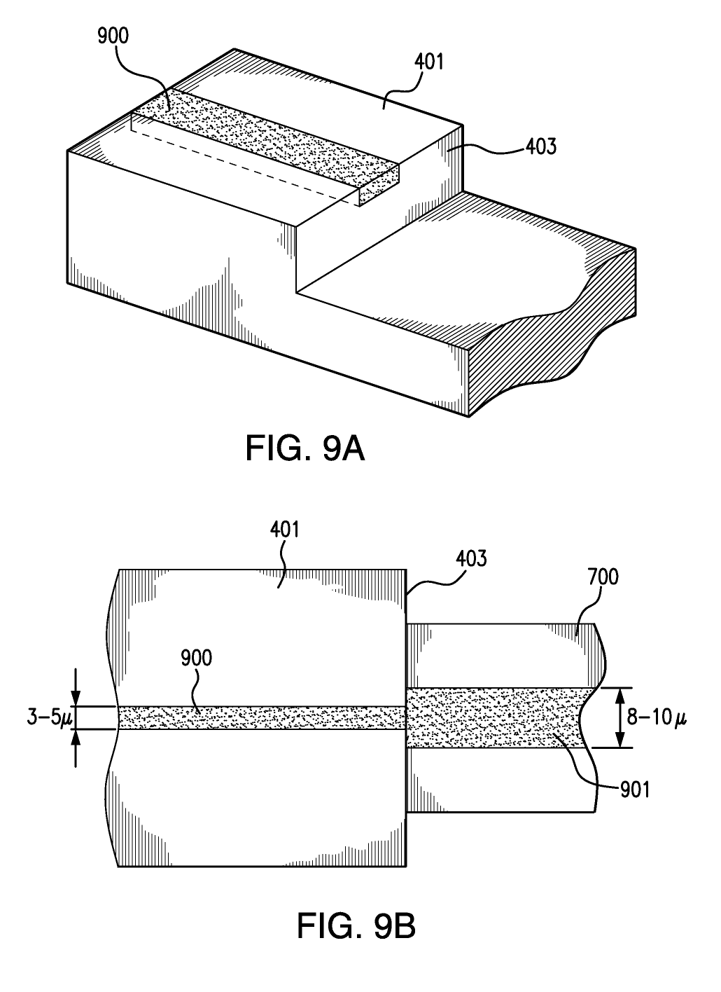

FIG. 9A is a perspective of a hybrid silicon/III-V compound semiconductor structure showing in one embodiment of the present disclosure a waveguide 900 disposed on the top surface 401 and extending longitudinally in the silicon body 400 to the edge 403.

FIG. 9B is a top view of the hybrid silicon/III-V compound semiconductor structure after the III-V compound semiconductor structure 700 is joined to the silicon body 400 that was depicted in FIG. 8A. In particular, one embodiment of the relative widths of the waveguides 900 and 702 are depicted.

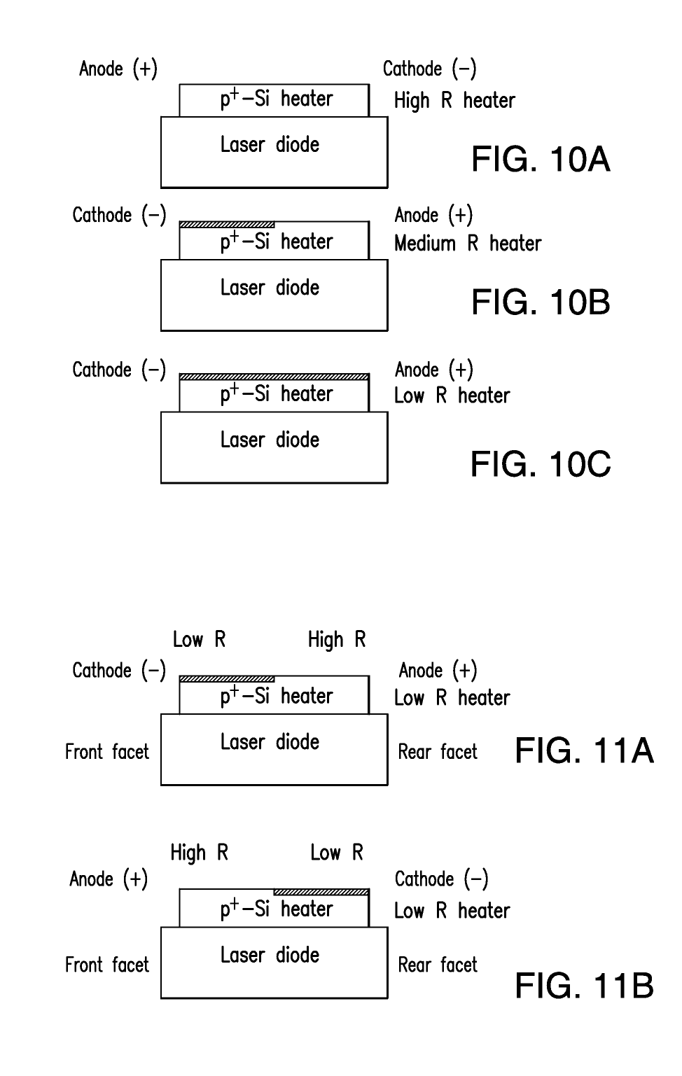

FIGS. 10A, 10B and 10C show an example of p+-Si heater thermal tuning by the electrical current. The electrical current can be determined and selected depending upon the level of SBS suppression needed for the laser. A feature of the use of such an adjustable method of selecting the temperature level p+-Si heater tuning offers substantial advantage over the conventional heater where the resistance is fixed and given by the resistivity and geometry of the metal line.

FIG. 10A is the first example of thermal tuning by electrical current through the channel illustrating the situation when no silicide line is formed in the semiconductor region, and the channel is at high resistance state.

FIG. 10B is an example of thermal tuning by the electrical current illustrating the situation where a short silicide line is formed in the semiconductor region, and the channel is at medium resistance state.

FIG. 100 is an example of thermal tuning by the electrical current illustrating the situation where a long silicide line is formed in the semiconductor region, and the channel is at low resistance state.

FIG. 11A is another embodiment of the present disclosure illustrating the control of the laser gain medium by implementation of a low resistance at the front laser section.

FIG. 11B is another embodiment of the present disclosure illustrating the control of the laser gain medium by implementation of a low resistance at the front laser section.

The resistance reduction associated with the silicide formation in the p+-Si stripe can effectively tune the resistance and tailor the thermal distribution along the laser cavity as appropriate for the intended application.

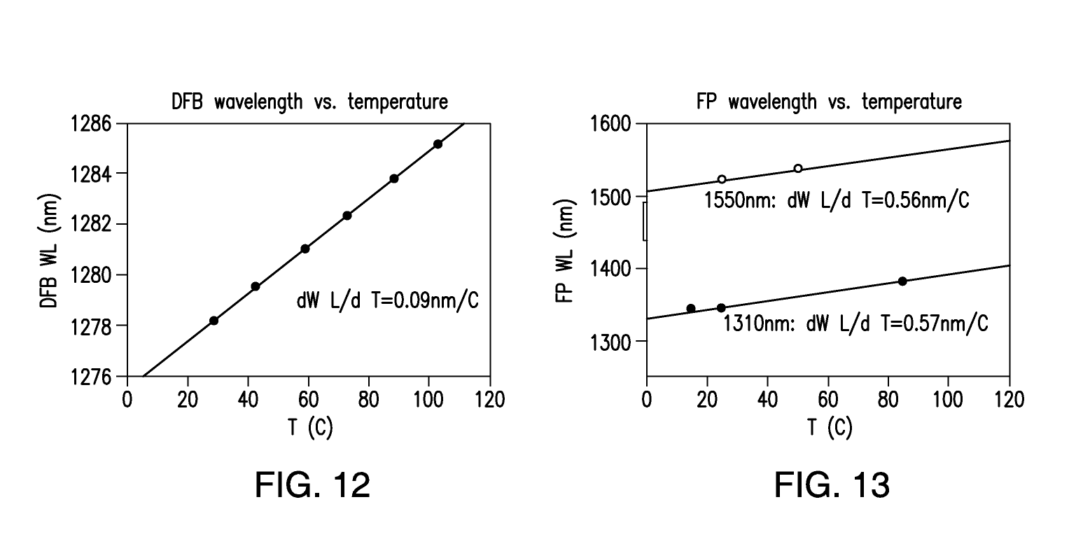

FIG. 12 shows the DFB wavelength InP laser as a function of temperature. The rate of wavelength shift per degree Celsius is about 0.09 nm/° C. For the p+-Si heater, the temperature tuning is expected to be about 300° C. This temperature variation would result in 27 nm in wavelength tuning.

FIG. 13 shows the FP wavelength of InP laser as a function of temperature. The Rate of wavelength shift per degree Celsius is about 0.45-0.60 nm/° C. For the p+-Si heater, the temperature tuning is expected to be about 300° C. This temperature variation would result in 135-180 nm in wavelength tuning.

Without further analysis, from the foregoing others can, by applying current knowledge, readily adapt the present disclosure for various applications. Such adaptations should and are intended to be comprehended within the meaning and range of equivalence of the following claims.

1. A method of adjusting an operational parameter in a III-V compound semiconductor device comprising:
providing a silicon substrate including a channel configured for silicide line formation as a function of current through the channel;
coupling the silicon substrate to the III-V compound semiconductor device so that the temperature of the silicon substrate is radiated to the III-V compound semiconductor device: and
controlling the current through the channel so that the temperature of the semiconductor device is adjusted to a predetermined level, thereby controllably adjusting the operational parameter of the semiconductor device.

2. A method as defined in claim 1, wherein the semiconductor device is a distributed feedback (DFB) or a Fabry Perot (FP) laser, the laser having a front facet and a rear facet, and wherein the channel extends longitudinally between the region adjacent to the front facet to the region adjacent to the rear facet.

3. A method as defined in claim 2, wherein the operational parameter is the wavelength of the emitted light from the laser.

4. A method as defined in claim 1, wherein the semiconductor device is composed of InP.

5. A method as defined in claim 3, wherein the wavelength of the laser changes by approximately 0.09 nm for each degree Celsius change in temperature of the semiconductor device.

6. A method as defined in claim 3, wherein the wavelength of the laser changes from 0.4 to 0.5 nm for each degree Celsius change in temperature of the semiconductor device.

7. A method as defined in claim 1, further comprising:
etching a first portion of the silicon substrate to provide a planar mounting surface;
doping a first surface of the first portion of the silicon substrate to form a first region of a conductivity type different from that of the substrate; and
forming a ohmic electrical contact to the first surface area;

8. A method as defined in claim 7, wherein a III-V compound semiconductor device has a metallized back surface, and is mounted on the mounting surface so that the metallized back surface of the III-V compound semiconductor device makes electrical contact with the electrical contact on the first surface area.

9. A method as defined in claim 1, wherein the silicon substrate is n conductivity type and the first portion of the silicon substrate is a p-conductivity type region disposed in the semiconductor substrate, the p-conductivity type region having (i) a first end and a second end forming a channel there between; (ii) a first electrical terminal composed of nickel or copper disposed on the first end of the p-conductivity type region; (iii) a second electrical terminal composed of nickel or copper disposed on the second end of the p-conductivity type region; and
wherein an electromigration-induced silicide line is formed in the channel between the first and the second electrical terminals when a current is applied to the terminals.

10. A method as defined in claim 1, wherein the channel is between 150 and 200 micrometers long and between 0.5 and 1.5 micrometers wide, and the applied current is between 60 and 90 mA.

11. A method as defined in claim 4, wherein current is applied so that a low resistance region is formed in the channel adjacent to the front facet, and a high resistance region is formed in the channel adjacent to the rear facet.

12. A method as defined in claim 4, wherein current is applied so that a low resistance region is formed in the channel adjacent to the rear facet, and a high resistance region is formed in the channel adjacent to the front facet.

13. A method as defined in claim 2, wherein the length of the silicide line is determined to provide a predetermined resistance level, and thereby a predetermined level of SBS suppression, and current is applied to the terminals to the extent required to implement the predetermined resistance level.

14. A method as defined in claim 2, wherein the silicide line extends from the terminal which is the cathode terminal to a point between the cathode terminal and the anode terminal so as to provide a predetermined resistance level.

15. A hybrid silicon/III-V compound semiconductor device comprising:
a silicon substrate including a channel configured for silicide line formation as a function of current through the channel; and
a semiconductor laser device implemented on the III-V compound semiconductor portion of the hybrid device mounted on the silicon substrate.

16. A device as defined in claim 15, wherein the silicon substrate is n conductivity type, and further comprising
a p-conductivity type region disposed in the semiconductor substrate, the p-conductivity type region having a first end and a second end forming said channel there between;
a first electrical terminal composed of nickel or copper disposed on the first end of the p-conductivity type region;
a second electrical terminal composed of nickel or copper disposed on the second end of the p-conductivity type region; and
wherein an electromigration-induced silicide line is formed in the channel between the first and the second electrical terminals when a current is applied to the terminals.

17. A device as defined in claim 16, wherein the laser has a front facet and a rear facet, and wherein the channel extends longitudinally between the region adjacent to the front facet to the region adjacent to the rear facet.

18. A device as defined in claim 17, wherein current is applied so that a low resistance region is formed in the channel adjacent to the front facet, and a high resistance region is formed in the channel adjacent to the rear facet.

19. A device as defined in claim 17, wherein current is applied so that a low resistance region is formed in the channel adjacent to the rear facet, and a high resistance region is formed in the channel adjacent to the front facet.

20. A device as defined in claim 17, wherein the silicide line extends a predetermined length from the terminal adjacent to the front facet of the laser, to a point in the channel between the front facet and the rear facet of the laser.
